(19) United States
(12) Patent Application Publication
(10) Pub. No.: US 2012/0241201 A1
(43) Pub. Date: Sep. 27, 2012

(54) CIRCUIT BOARD

(75) Inventors: HUA-LI ZHOU, Shenzhen City (CN); CHIA-NAN PAI, Tu-Cheng (TW); SHOU-KUO HSU, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/107,950

(22) Filed: May 15, 2011

(30) Foreign Application Priority Data
Mar. 21, 2011 (CN) 201110067612.9

(51) Int. Cl. H05K 1/09

(52) U.S. Cl. 174/257

(57) ABSTRACT

A circuit board includes a substrate and a copper layer positioned on the substrate. The copper layer includes a BGA area and a non-BGA area, and includes traces. The widths of the traces in the BGA area are smaller than the widths of the traces in the non-BGA area, the dielectric coefficient of the substrate in the BGA area is greater than the dielectric coefficient of the substrate in the non-BGA area for keeping the impedance of the traces consistent in the BGA area and in the non-BGA area.

### BACKGROUND

1. Technical Field

The present disclosure relates to a circuit board.

2. Description of Related Art

Trace impedances of circuit boards must be consistent throughout all the traces for good signal transmitting ability. Yet, at some positions of the trace, for example, where the trace is connected to a ball grid array (BGA), the impedance may be different.

Therefore, it is desirable to provide a circuit board, which can overcome the limitations described.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic.

FIG. 1 is a schematic, sectional view of a circuit board at a non-BGA area according to a first embodiment.

FIG. 2 is a schematic, sectional view of the circuit board of FIG. 1 at a BGA area.

FIG. 3 is a schematic, sectional view of a circuit board carrying a single micro-strip.

FIG. 4 is a schematic, sectional view of a circuit board at a non-BGA area according to a second embodiment.

FIG. 5 is a schematic, sectional view of a circuit board of FIG. 4 at a BGA area.

FIG. 6 is a schematic, sectional view of a circuit board at a non-BGA area carrying differential micro-strips.

### DETAILED DESCRIPTION

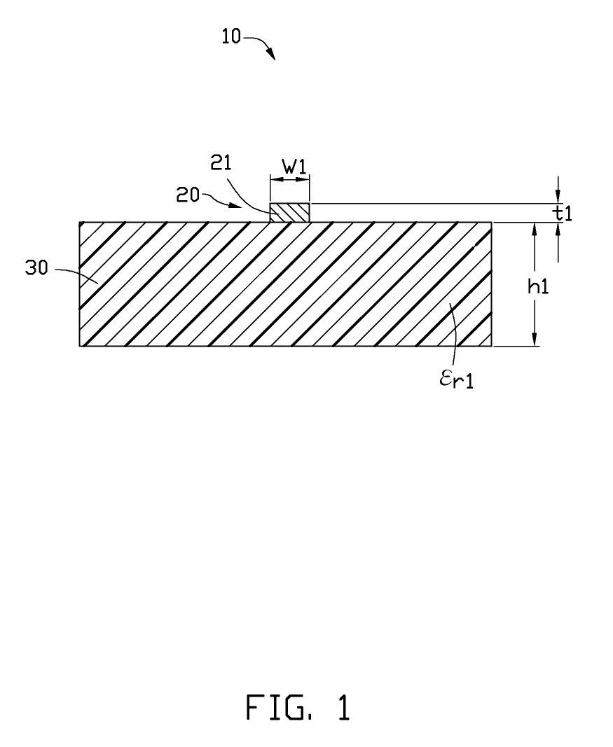

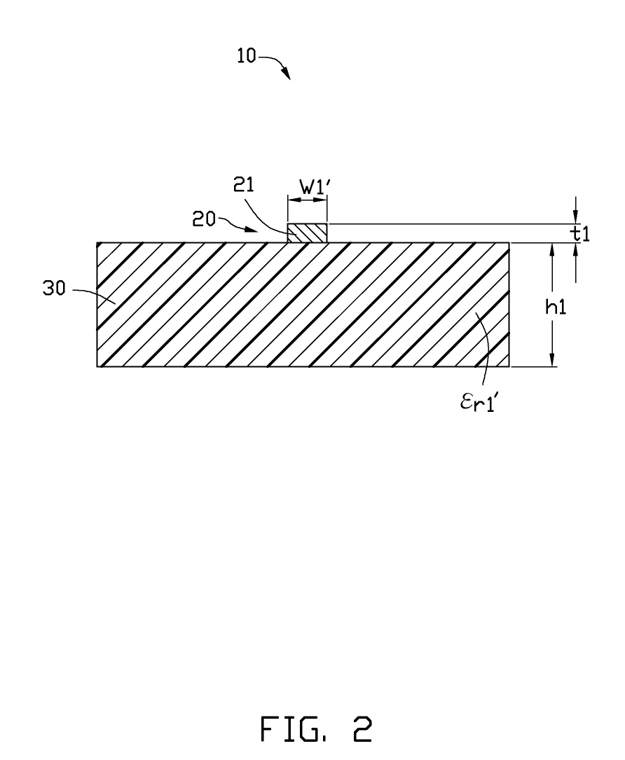

Referring to FIGS. 1 and 2, a circuit board 10 according to a first embodiment is disclosed. The circuit board 10 includes at least a substrate 30 and a copper layer 20 formed on the substrate 30.

The substrate 30 is made up of insulating material. In this embodiment, the substrate 30 is made of fiberglass.

The copper layer 20 includes components (not shown) and traces 21, for simplicity, only one trace 21 is shown. In this embodiment, the trace 21 is a single micro-strip. The copper layer 20 is divided into a BGA area for carrying a BGA (not shown) and a non-BGA area. The width of the trace 21 in the non-BGA area is represented as w1, the width of the trace 21 in the BGA area is represented as w1′, and w1 is wider than w1′.

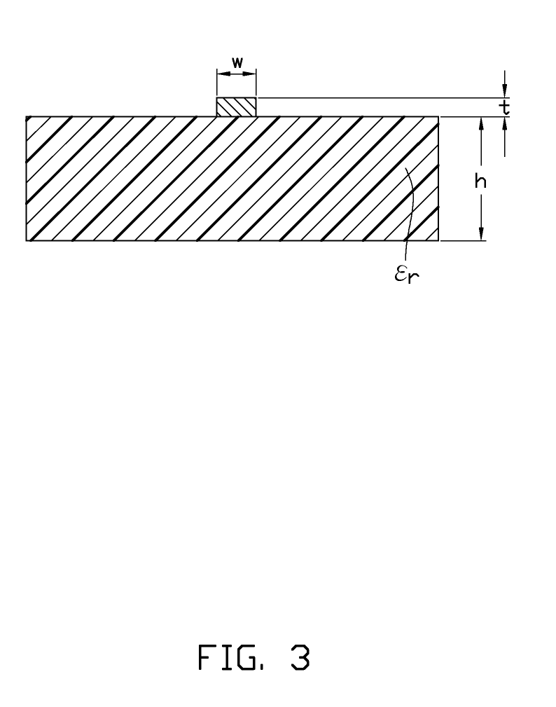

Referring to FIG. 3, as the trace 21 is a single micro-strip, the impedance of the trace 21 can be calculated according to the following formula:

$${Z}_{Single} = \frac{87}{\sqrt{{ɛ}_{r} + 1.41} } ln \frac{5.98 h}{0.8 w + t} , \qquad ( formula 1 )$$

wherein Z_{single} represents the impedance, εᵣ represents the dielectric coefficient of the substrate 30, h represents the height of the substrate 30, w represents the width of the trace 21, t represents the height of the trace 21.

As the width of the trace 21 in the non-BGA area is wider than in the BGA area, according to formula 1, if other factors in the formula 1 remain unchanged, the impedance of the trace 21 in the non-BGA area will be smaller than in the BGA area. For the purpose of keeping the impedance of the trace 21 consistent, the dielectric coefficient of the substrate 30 in the BGA area is increased accordingly.

Various methods for increasing the dielectric coefficient of the substrate 30 in the BGA area can be used. For example, when the substrate 30 is made fiberglass, because the dielectric coefficient of glass fibers is greater than that of resin, a ratio of the glass fiber to resin in the fiberglass used in the BGA area is larger than that in the non-BGA area.

According to formula 1, for making the impedance of the trace 21 consistent, the dielectric coefficient of the substrate 30 satisfies the following formula:

$${ɛ}_{r 1}^{′} = {( \frac{ln 5.98 h 1 - ln ( 0.8 w {1}^{′} - t 1 )}{ln 5.98 h 1 - ln ( 0.8 w 1 + t 1 )} )}^{2} \times ( {ɛ}_{r 1} + 1.41 ) - 1.41 , \qquad ( formula 2 )$$

wherein εᵣ₁ is the dielectric coefficient of the substrate 30 in the non-BGA area, εᵣ₁′ is the dielectric coefficient of the substrate 30 in the BGA area, h1 is the height of the substrate 30, w1 is the width of the trace 21 in the non-BGA area, w1′ is the width of the trace 21 in the BGA area, t1 is the height of the trace 21.

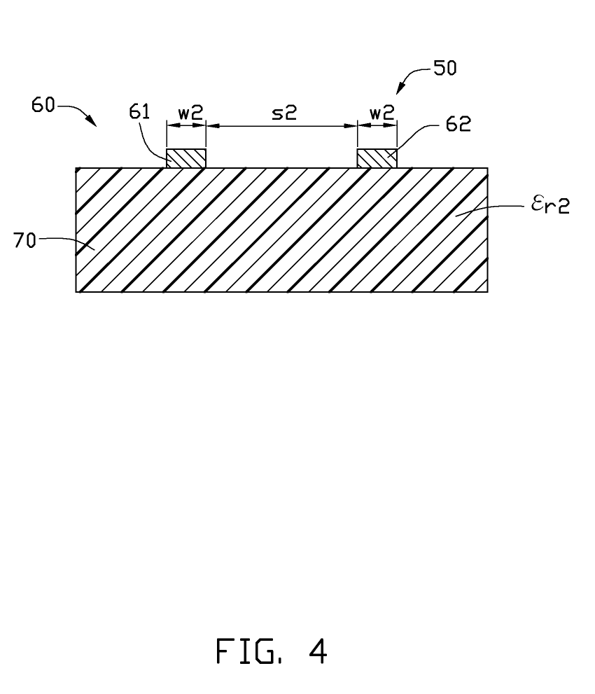

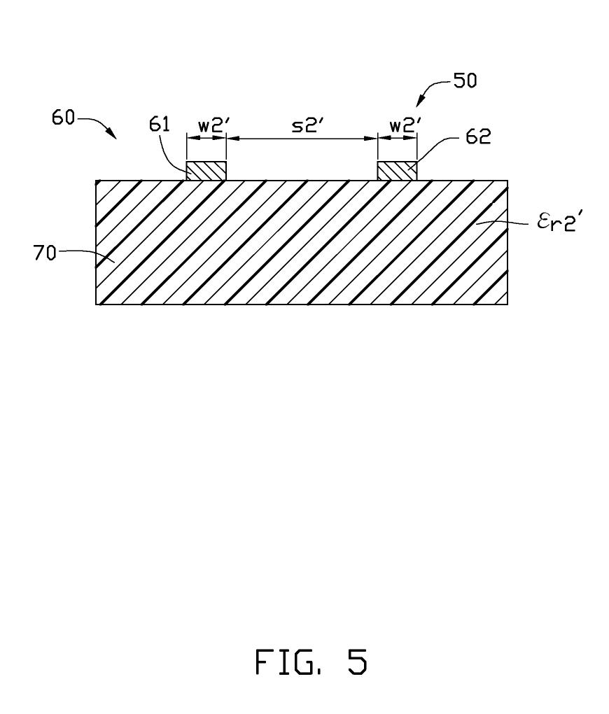

Referring to FIGS. 4 and 5, a circuit board 50 according to a second embodiment is disclosed. The circuit board 50 is similar to the circuit board 10 except that traces 61, 62 of the circuit board 50 are differential micro-strips. The widths w2 of the traces 61, 62 in the non-BGA area are wider than the widths w2′ of the traces 61, 62 in the BGA area. The gap s2 between the traces 61, 62 in the non-BGA area is wider than the gap s2′ between the traces 61, 62 in the BGA area.

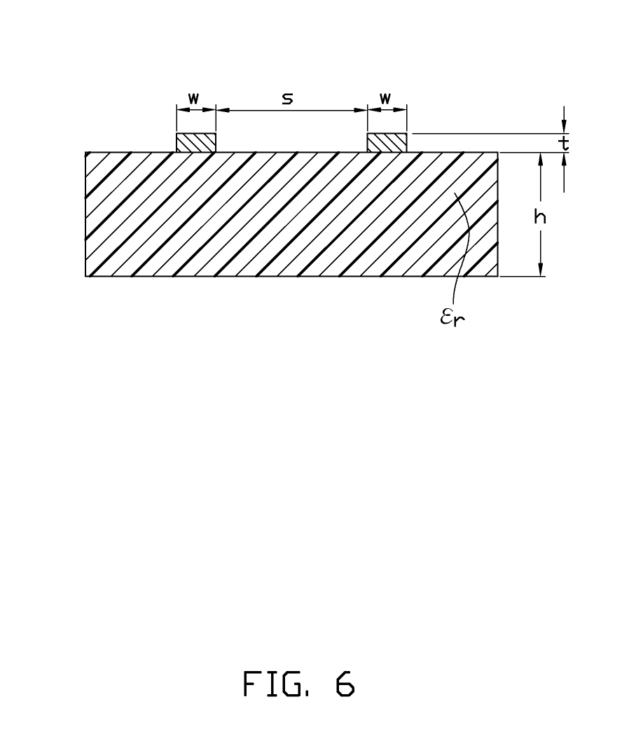

Referring to FIG. 6, as the traces 61, 62 are differential micro-strips, the impedance of the traces 61, 62 can be calculated according to the following formula:

$${Z}_{Diff} = ( 2 \times {Z}_{Single} ) \times ( 1 - 0.48 \times {e}^{\frac{- 0.96 \times s}{h}} ) , \qquad ( formula 3 )$$

wherein Z_{Single} is the impedance of the single micro-strip which can be calculated according to formula 1, s is the gap between the traces 61, 62, h is the height of the substrate 70.

For making the impedance of the traces 61, 62 consistent, the dielectric coefficient εᵣ₂′ the substrate 70 in the BGA area is made greater than the dielectric coefficient εᵣ₂ of the substrate 70 in the non-BGA area. The ratio of εᵣ₂′ to εᵣ₂ can be calculated according to formula 3.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A circuit board, comprising:
a substrate; and
a copper layer positioned on the substrate, the copper layer comprising a BGA area and a non-BGA area, and comprising traces;
wherein the widths of the traces in the BGA area are smaller than the widths of the traces in the non-BGA area, the dielectric coefficient of the substrate in the BGA area is greater than the dielectric coefficient of the substrate in the non-BGA area for keeping the impedance of the traces consistent in the BGA area and in the non-BGA area.

2. The circuit board of claim 1, wherein the traces are single micro-strips.

3. The circuit board of claim 2, wherein the dielectric coefficient of the substrate satisfies the following formula:
$${ɛ}_{r 1}^{′} = {( \frac{ln 5.98 h 1 - ln ( 0.8 w {1}^{′} + t 1 )}{ln 5.98 h 1 - ln ( 0.8 w 1 + t 1 )} )}^{2} \times ( {ɛ}_{r 1} + 1.41 ) - 1.41 ,$$
and wherein εᵣ₁ is the dielectric coefficient of the substrate in the non-BGA area, εᵣ₁′ is the dielectric coefficient of the substrate in the BGA area, h1 is the height of the substrate, w1 is the width of the traces in the non-BGA area, w1′ is the width of the traces in the BGA area, t1 is the height of the traces.

4. The circuit board of claim 1, wherein the traces are differential micro-strips.

5. The circuit board of claim 1, wherein the substrate is made of fiberglass.
